(19) United States
(12) Patent Application Publication
(10) Pub. No.: US 2025/0108982 A1
(43) Pub. Date: Apr. 3, 2025

(54) CONVEYANCE APPARATUS, SHAPING APPARATUS, AND ARTICLE MANUFACTURING METHOD

(71) Applicant: CANON KABUSHIKI KAISHA, Tokyo (JP)

(72) Inventor: RYUSUI MURAI, Tochigi (JP)

(21) Appl. No.: 18/889,675

(22) Filed: Sep. 19, 2024

(30) Foreign Application Priority Data
Sep. 28, 2023 (JP) 2023-168866

(51) Int. Cl. B65G 47/90

(52) U.S. Cl. CPC B65G 47/907; B65G 47/905; B65G 2203/0283

(57) ABSTRACT

The present invention provides a conveyance apparatus comprising: a first hand configured to hold a first member; a second hand configured to hold a second member; a controller configured to control a first process of conveying the first member to a first holder with the first hand and a second process of conveying the second member to a second holder with the second hand, wherein in the first process, after the first hand is driven, the first holder is moved so as to bring the first member into contact with the first holder, and the controller is configured to control driving of the second hand in the second process, based on a driving error in the driver which is determined from movement of the first holder in the first process.

### BACKGROUND OF THE INVENTION

### Field of the Invention

The present invention relates to a conveyance apparatus, a shaping apparatus, and an article manufacturing method.

### Description of the Related Art

A lithography apparatus that forms a pattern on a substrate by using an original can be provided with, for example, a conveyance apparatus that holds and conveys members such as an original and a substrate. Such a conveyance apparatus sometimes experiences an abnormality in which the actual position of a hand that holds and moves a member shifts from the design position (target position) due to changes over time and ambient environments. The occurrence of such an abnormality may cause the hand or the member during the conveyance of the member with the hand to unintentionally come into contact with another member in the lithography apparatus. This may damage the hand and the members. Japanese Patent Laid-Open No. 2017-139261 discloses a technique of acquiring information about a transport height position at which a substrate is transported during the upward/downward movement of a substrate holder based on the time-series data of pressure in a suction path which changes depending on whether the substrate is held by the substrate holder.

Some conveyance apparatus is configured to drive each of a plurality of hands in the height direction by driving a support member that supports the plurality of hands in the height direction. Such a conveyance apparatus is required to obtain a driving error at the time of driving a support member and accurately control the conveyance of a member with each of a plurality of hands.

### SUMMARY OF THE INVENTION

The present invention provides, in, for example, a conveyance apparatus configured to drive a support member supporting a plurality of hands in the height direction, a technique advantageous in accurately controlling the conveyance of a member with each hand.

According to one aspect of the present invention, there is provided a conveyance apparatus comprising: a first hand configured to hold a first member; a second hand configured to hold a second member; a support member configured to support the first hand and the second hand; a driver configured to drive the first hand and the second hand in a height direction by driving the support member in the height direction; and a controller configured to control a first process of conveying the first member to a first holder with the first hand and a second process of conveying the second member to a second holder with the second hand, wherein the first holder is configured to move in the height direction, wherein in the first process, after the first hand is driven in the height direction by the driver, the first holder is moved in the height direction so as to bring the first member held by the first hand into contact with the first holder, and wherein the controller is configured to control driving of the second hand by the driver in the second process, based on a driving error in the driver which is determined from movement of the first holder in the first process.

Further features of the present invention will become apparent from the following description of exemplary embodiments with reference to the attached drawings.

### BRIEF DESCRIPTION OF THE DRAWINGS

FIG. 1 is a schematic view showing an example of the arrangement of a planarization apparatus;

FIG. 2 is a schematic view showing an example of the arrangement of a planarization module;

FIGS. 3A and 3B are schematic views showing an example of the arrangement of a conveyance apparatus;

FIG. 4 is a flowchart showing a mold conveyance process according to the first embodiment;

FIGS. 5A to 5C are schematic views for explaining the operations of the conveyance apparatus and the planarization module in the mold conveyance process according to the first embodiment;

FIG. 6 is a flowchart showing a substrate conveyance process according to the first embodiment;

FIGS. 7A to 7C are schematic views for explaining the operations of the conveyance apparatus and the planarization module in the substrate conveyance process according to the first embodiment;

FIG. 8A is flowchart showing a mold conveyance process according to the second embodiment;

FIG. 8B is flowchart showing the mold conveyance process according to the second embodiment;

FIGS. 9A to 9C are schematic views for explaining the operations of a conveyance apparatus and a planarization module in the mold conveyance process according to the second embodiment;

FIG. 10 is a flowchart showing an interval detection process according to the third embodiment;

FIGS. 11A and 11B are schematic views for explaining the operations of a conveyance apparatus and a planarization module in an interval correction process according to the third embodiment;

FIGS. 12A and 12B are schematic views showing a modification of the conveyance apparatus;

FIGS. 13A to 13F are views for explaining an article manufacturing method (imprint process); and

FIGS. 14A to 14D are views for explaining an article manufacturing method (planarization process).

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made an invention that requires all such features, and multiple such features may be combined as appropriate. Furthermore, in the attached drawings, the same reference numerals are given to the same or similar configurations, and redundant description thereof is omitted.

In the specification and the accompanying drawings, directions will be indicated on an XYZ coordinate system in which directions parallel to the surface of a substrate are defined as the X-Y plane, unless otherwise specified. Directions parallel to the X-axis, the Y-axis, and the Z-axis of the XYZ coordinate system are the X direction, the Y direction, and the Z direction, respectively. A rotation about the X-axis, a rotation about the Y-axis, and a rotation about the Z-axis are θX, θY, and θZ, respectively. Control or driving concerning the X-axis, the Y-axis, and the Z-axis means control or driving concerning a direction parallel to the X-axis, a direction parallel to the Y-axis, and a direction parallel to the Z-axis, respectively. In addition, control or driving concerning the θX-axis, the θY-axis, and the θZ-axis means control or driving concerning a rotation about an axis parallel to the X-axis, a rotation about an axis parallel to the Y-axis, and a rotation about an axis parallel to the Z-axis, respectively. In addition, a position is information that can be specified based on coordinates on the X-, Y-, and Z-axes, and an orientation is information that can be specified by values on the θX-, θY-, and θZ-axes.

A shaping apparatus to which the conveyance apparatus according to the present invention can be applied is an apparatus that performs a shaping process of shaping a composition on a substrate by pressing a mold against the composition. Examples of the shaping apparatus are an imprint apparatus and a planarization apparatus. The imprint apparatus is an apparatus that brings a mold including a pattern having concave and convex portions into contact with a composition (imprint material) on a substrate to form (transfer) the pattern on the composition. The shaping process performed by the imprint apparatus will sometimes be referred to as an imprint process hereinafter. The planarization apparatus is an apparatus that planarizes the surface of a composition by bringing a mold having a flat surface into contact with the composition on a substrate. The shaping process performed by the planarization apparatus will sometimes be referred to as a planarization process hereinafter. In the following description, the planarization apparatus will be exemplified as a shaping apparatus but arrangements/processes of the planarization apparatus can also be applied to the imprint apparatus.

### First Embodiment

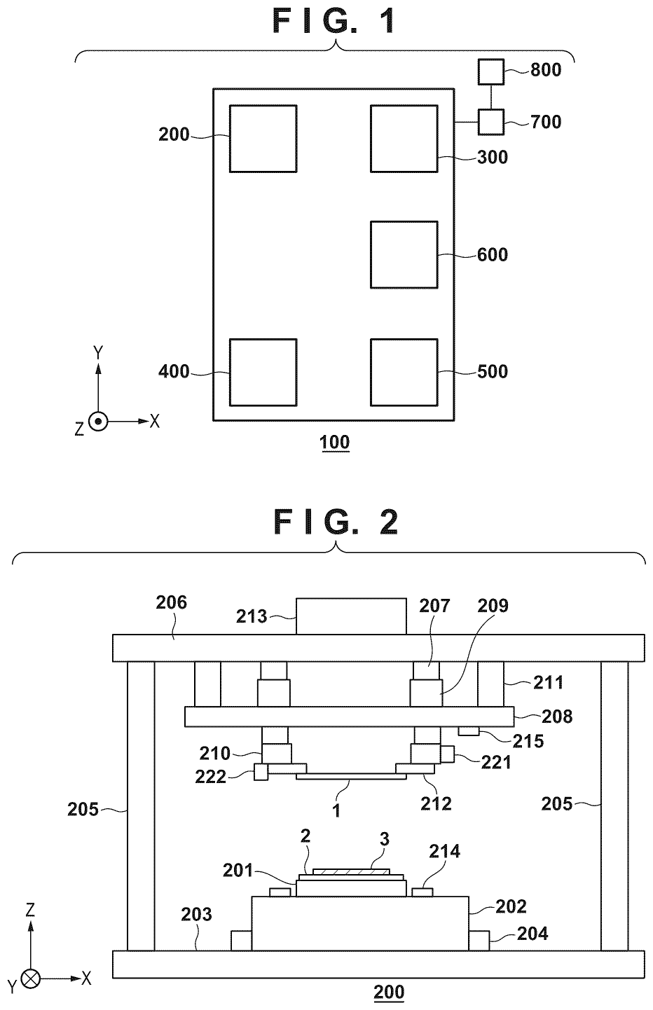

The first embodiment of the present invention will be described. FIG. 1 is a schematic view showing an example of the arrangement of a planarization apparatus 100 according to this embodiment. As described above, the planarization apparatus 100 is an example of a shaping apparatus that shapes a composition 3 on a substrate 2 by using a mold 1. More specifically, the planarization apparatus 100 can shape a planarized film on the substrate 2 by curing the uncured composition 3 suppled (applied) onto the substrate 2 while the mold 1 having a flat surface is in contact with the composition 3 and separating the mold 1 from the cured composition 3.

The mold 1 can be formed from a material having ultraviolet transparency. Examples of the material of the mold 1 include glass made of a material selected from silicon oxide, boron oxide, sodium carbonate, magnesium oxide, calcium oxide, and aluminum oxide, polymethylmethacrylate resin, polycarbonate resin, a photo-curable film, and a metal film. In the following description, a flat plate made of silica glass will be exemplified as the mold 1, but mold 1 is not limited to the flat plate. In addition, the mold 1 preferably has a disk-like shape having a diameter larger than 300 mm and smaller than 500 mm and having a thickness equal to or more than 0.25 mm and less than 2 mm, but a shape of the mold 1 is not limited to the disk-like shape.

For example, glass, ceramics, a metal, a semiconductor, or a resin can be used as a material for the substrate 2. The surface of the substrate 2 may be provided with a member made of a material different from the substrate 2 as needed. The substrate 2 is, for example, a silicon wafer, a compound semiconductor wafer, or silica glass. In this embodiment, the substrate 2 is formed of a material arbitrarily selected from, for example, silicon, silicon carbide, silicon oxide, aluminum oxide, aluminum nitride, gallium oxide, gallium nitride, gallium phosphide, gallium arsenide, and germanium. Alternatively, the substrate 2 may be the one whose adhesiveness with a composition has been improved by surface treatment such as silane coupling treatment, silazane treatment, or deposition of an organic thin film. In the following description, a silicon wafer made of silicon will be exemplified as the substrate 2, but the substrate 2 is not limited to the silicon wafer. The silicon wafer as the substrate 2 typically has a disk-like shape having a diameter of 300 mm, but a shape of the substrate is not limited to the disk-like shape.

The composition 3 to be used is a photo-curable composition that is cured by light irradiation or a thermosetting composition that is set by heat application. A photo-curable composition or thermosetting composition is sometimes called a shapable material. In the following description, a photo-curable composition that is cured by irradiation with light having a wavelength of 200 nm to 380 nm will be exemplified as the composition 3, but the composition 3 is not limited to the photo-curable composition. The photo-curable composition contains at least a polymerizable compound and a photopolymerization initiator, and may further contain a nonpolymerizable compound or a solvent, as needed. The nonpolymerizable compound is at least one type of material selected from a group consisting of a sensitizer, a hydrogen donor, an internal mold release agent, a surfactant, an antioxidant, a polymer component, and the like. The viscosity (the viscosity at 25° C.) of the viscous material is, for example, from 1 mPa·s (inclusive) to 100 mPa·s (inclusive).

As shown in FIG. 1, the planarization apparatus 100 according to this embodiment can include a planarization module 200, a supply module 300, a loading station 400, an unloading station 500, a conveyance apparatus 600, a controller 700, a notification unit 800. The conveyance apparatus 600 is an apparatus that holds and conveys the mold 1 and/or the substrate 2. The term “conveyance” used in the following description indicates that the conveyance apparatus 600 holds and moves the mold 1 and/or the substrate 2 from a predetermined departure point to a predetermined arrival point.

The planarization module 200 is a unit that performs a planarization process of planarizing the composition 3 on the substrate 2 using the mold 1 as a shaping process. The planarization module 200 forms a planarized film (planarized layer) on the substrate 2 by curing the composition 3 while the mold 1 is in contact with the composition 3 on the substrate 2 and separating the mold 1 from the cured composition 3. Note that a detailed arrangement example of the planarization module 200 will be described later.

The supply module 300 (application module) is a unit that supplies (applies) the composition 3 onto the substrate 2 as a preprocess for a planarization process by the planarization module 200. The conveyance apparatus 600 conveys the substrate 2, to which the composition 3 is supplied by the supply module 300, to the planarization module 200. Note that the supply module 300 may be provided as a constituent element of the planarization module 200.

The loading station 400 is an interface unit for loading the mold 1 and/or the substrate 2 from the outside of the apparatus into the planarization apparatus 100. The loading station 400 may be understood as an interface unit that transports the mold 1 and/or the substrate 2 between the outside of the apparatus and the planarization apparatus 100. The conveyance apparatus 600 conveys the mold 1 loaded from the outside of the apparatus into the loading station 400 to the planarization module 200. In addition, after the conveyance apparatus 600 conveys the substrate 2 loaded from the outside of the apparatus into the loading station 400 to the supply module 300 and the composition 3 is supplied, the conveyance apparatus 600 conveys the substrate 2 to the planarization module 200.

The unloading station 500 is an interface unit for unloading the mold 1 and/or the substrate 2 from the planarization apparatus 100 to the outside of the apparatus. The unloading station 500 may be understood as an interface unit that transports the mold 1 and/or the substrate 2 between the outside of the apparatus and the planarization apparatus 100. The conveyance apparatus 600 conveys the mold 1 used for a planarization process by the planarization module 200 to the unloading station 500. The conveyance apparatus 600 also conveys the substrate 2 having undergone the planarization process by the planarization module 200 to the unloading station 500. The substrate 2 may be conveyed to the unloading station 500 immediately after the end of the planarization process but may be conveyed to the unloading station 500 at a timing after the lapse of a predetermined time since the end of the planarization process.

The conveyance apparatus 600 is an apparatus that conveys the mold 1 and/or the substrate 2. The conveyance apparatus 600 includes a plurality of hands that respectively hold members. More specifically, the conveyance apparatus 600 includes a first hand that holds the mold 1 as a first member and a second hand that holds the substrate 2 as a second member. An example of the arrangement of the conveyance apparatus 600 will be described in detail later.

The controller 700 controls each unit (the planarization module 200, the supply module 300, the conveyance apparatus 600, and the like) in the planarization apparatus 100. The controller 700 can be implemented by an information processing apparatus (computer) including a processor such as a central processing unit (CPU) and storage units (memories) such as a ROM and a RAM. The controller 700 may be implemented by, for example, a Programmable Logic Device (PLD) such as a Field Programmable Gate Array (FPGA), an Application Specific Integrated Circuit (ASIC), a general-purpose computer incorporating programs, or a combination of all or some of these components.

The notification unit 800 notifies the operator of the planarization apparatus 100 of various types of information. For example, the notification unit 800 may include a display unit (display) and perform notification by displaying various types of information on the display unit. Alternatively, the notification unit 800 may include an audio output unit and perform notification by outputting various types of information in an audio form from the audio output unit. In this case, the planarization apparatus 100 according to this embodiment is provided with the supply module 300 as a preprocessing module that performs a preprocess for a planarization process, but the preprocessing module is not limited to the supply module 300. For example, the supply module 300 may be additionally or alternatively provided, as a preprocessing module, a heat treatment module that adjusts the temperature of the substrate 2, a film formation module that forms a thin film on the substrate 2, or an alignment module that aligns the substrate 2. In this case, the conveyance apparatus 600 can convey the substrate 2 from the loading station 400 to the planarization module 200 through the preprocessing module. The composition 3 may be supplied (applied) onto the substrate 2 on the outside of the planarization apparatus 100. In this case, the substrate 2 may be conveyed from the loading station 400 to the planarization module 200 without through the supply module 300.

According to an example of the arrangement of the planarization apparatus 100 in FIG. 1, the planarization apparatus 100 is not provided with a postprocessing module that performs a postprocess for a planarization process, but the planarization apparatus 100 may be provided with the postprocessing module. For example, the planarization apparatus 100 may be provided with, for example, as a postprocessing module, the above heat treatment module or alignment module presented as a preprocessing module. In this case, the conveyance apparatus 600 can convey the substrate 2 from the planarization module 200 to the unloading station 500 through the postprocessing module.

Like the substrate 2, the mold 1 may be conveyed from the loading station 400 to the planarization module 200 through the preprocessing module or may be conveyed from the planarization module 200 to the unloading station 500 through the postprocessing module. Note that the planarization apparatus 100 may be provided with a carrier (storing unit) aimed at temporarily storing or retreating the mold 1 and/or the substrate 2.

The planarization apparatus 100 according to this embodiment shown in FIG. 1 is provided with one each of the planarization module 200, the supply module 300, the loading station 400, the unloading station 500, and the conveyance apparatus 600. However, for example, a plurality of arbitrary modules, stations, and/or carriers may be arranged inside or outside the apparatus.

### Example of Arrangement of Planarization Module

An example of the arrangement of the planarization module 200 will be described next with reference to FIG. 2. FIG. 2 is a schematic view showing the example of the arrangement of the planarization module 200. As shown in FIG. 2, the planarization module 200 can include a substrate chuck 201, a substrate stage 202, a base 203, and driving mechanisms 204. In addition, the planarization module 200 can include support columns 205, a plate 206, guides 207, a base 208, driving mechanisms 209, a head 210, support columns 211, and mold chucks 212. The planarization module 200 further includes an irradiation unit 213, upward sensors 214, and a downward sensor 215. Although the planarization module 200 according to this embodiment can be controlled by the controller 700 of the planarization apparatus 100, a controller for controlling the planarization module 200 may be individually provided.

The substrate chuck 201 functions as a holder (second holder) that is supported by the substrate stage 202 and holds the substrate 2. Schemes by which the substrate chuck 201 sucks and holds the substrate 2 include a vacuum suction scheme, an electrostatic suction scheme, and the like. When the vacuum suction scheme is to be used, a concave portion communicating with a negative pressure generator is formed in the surface (holding surface) of the substrate chuck 201. The substrate chuck 201 can hold the substrate 2 by causing the negative pressure generator to generate a negative pressure in the convex portion while the substrate 2 is placed on the holding surface. In addition, the substrate chuck 201 has holding pins (not shown in FIG. 2) that protrude from the holding surface at the time of conveyance of the substrate 2 by the conveyance apparatus 600 and hold the substrate 2. The holding pins can move up and down so as to protrude from the holding surface of the substrate chuck 201 and retreat into the holding surface.

The substrate stage 202 is placed on the base 203 and is driven in the X and Y directions on the base 203 by the driving mechanisms 204. The driving mechanisms 204 can be implemented by, for example, an actuator such as a stepping motor, a linear motor, or an air cylinder. In this embodiment, the driving mechanisms 204 are configured to drive the substrate stage 202 (the substrate 2) along the X-axis or the Y-axis as a drive axis. However, for example, the driving mechanisms 204 may be configured to drive the substrate stage 202 along an axis (for example, the Z-axis) other than the X-axis and the Y-axis as a drive axis. In addition, the substrate stage 202 may have a rotating mechanism and drive the substrate stage 202 in a rotating direction around the X-axis and the Y-axis and/or the Z-axis. The substrate stage 202 may be configured to drive the holding pins that hold the substrate 2.

The support columns 205 are placed on the base 203 and supported by the base 203. The plate 206 is placed on the support columns 205 and supported by the support columns 205. The guides 207 are suspended from the plate 206 and extend through the base 208 to hold the head 210. The base 208 is placed under the support columns 211 and suspended from the plate 206 through the support columns 211.

The driving mechanisms 209 drives the head 210 in the Z direction along the guides 207. The driving mechanisms 209 can be implemented by, for example, an actuator such as a stepping motor, a linear motor, or a voice coil motor. In addition, the planarization module 200 can include a position detector 221 that detects the position (height) of the mold chucks 212 (holding surface) by using, for example, an encoder or an interferometer.

The mold chucks 212 are placed under the head 210 and supported by the head 210. The mold chucks 212 function as holders (first holders) that hold the mold 1 and are configured to be movable in the height direction (Z direction) by the driving mechanisms 209. Schemes by which the mold chucks 212 suck and hold the mold 1 include, for example, a vacuum suction scheme and an electrostatic suction scheme. The planarization module 200 includes a mold detector 222 (mold detection sensor) that detects whether the mold 1 is held by the mold chucks 212. When, for example, the mold chucks 212 is to hold the mold 1 by using the vacuum suction scheme, the mold detector 222 can detect, by detecting a suction pressure for the mold 1 by the mold chucks 212, whether the mold 1 is held by the mold chucks 212.

The irradiation unit 213 is a unit (curing unit) that cures the composition 3 on the substrate 2 by irradiating the composition 3 with light. The irradiation unit 213 can include a light source that emits light (for example, ultraviolet light) for curing the composition 3 and an optical system for irradiating the composition 3 on the substrate 2 with the light emitted from the light source. The planarization module 200 according to this embodiment brings the mold 1 into contact with the composition 3 on the substrate 2 by causing the driving mechanisms 209 to drive the mold chucks 212 in the −Z direction and causing the irradiation unit 213 to irradiate the composition 3 with light in this state. Light from the irradiation unit 213 is applied to the composition 3 on the substrate 2 through the base 208 and the mold 1. This makes it possible to cure the composition 3 infilled between the mold 1 and the substrate 2. The driving mechanisms 209 can separate the mold 1 from the cured composition 3 by driving the mold chucks 212 in the +Z direction. This makes it possible to form a planarized film made of the cured composition 3 on the substrate 2.

The upward sensors 214 are placed on the upper surface of the substrate stage 202 and detect the height of a member placed above the upward sensors 214 by measuring the distance to the member in the Z direction. If, for example, a member located at the lowest position in the measurement range in the Z direction is the substrate 2, the upward sensors 214 detect the height of the substrate 2 by measuring the distance to the substrate 2 in the Z direction. The upward sensors 214 can be, for example, displacement sensors using a spectral interference scheme. In the case in FIG. 2, the two upward sensors 214 are provided, but one or three or more upward sensors 214 may be provided. In addition, the upward sensors 214 may have, singly or in group, a function of measuring the tilt of the substrate 2 or the mold 1 in the X direction, the tilt thereof in the Y direction, and/or the central position thereof.

The downward sensor 215 (detector) is placed on the lower surface of the base 208 and detects the height of a member placed below the downward sensor 215 by measuring the distance to the member in the Z direction. If, for example, a member located at the uppermost position in the measurement range in the Z direction is the mold 1, the downward sensor 215 detects the height of the mold 1 by measuring the distance to the mold 1 in the Z direction. The downward sensor 215 can be, for example, a displacement sensor using a spectral interference scheme. In the case in FIG. 2, one downward sensor 215 is provided, but a plurality of downward sensors 215 may be provided. In addition, the downward sensors 215 may have, singly or in group, a function of measuring the tilt of the mold 1 or the substrate 2 in the X direction, the tilt thereof in the Y direction, and/or the central position thereof.

In the planarization module 200, the mold 1 is conveyed below the mold chucks 212 by the conveyance apparatus 600 and held by the mold chucks 212. In addition, the substrate 2 is conveyed above the substrate chuck 201 by the conveyance apparatus 600 and held by the substrate chuck 201. A method of conveying the mold 1 and the substrate 2 by the conveyance apparatus 600 will be described later.

### Example of Arrangement of Conveyance Apparatus

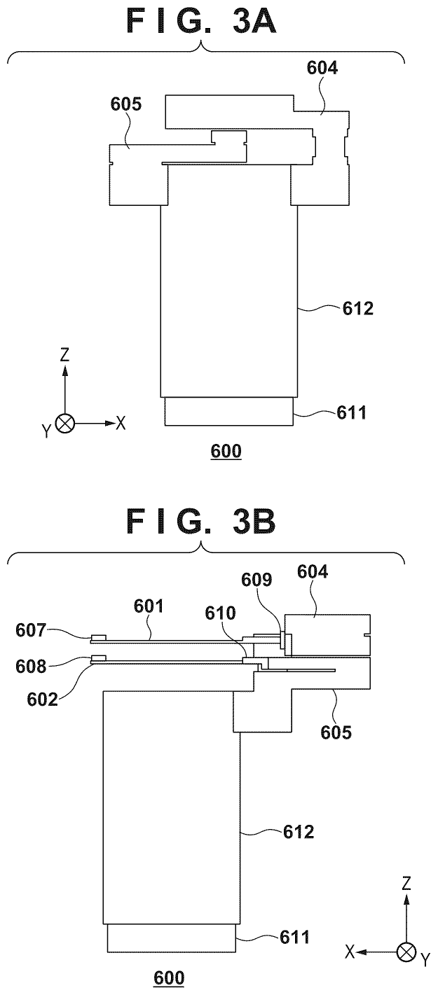

An example of the arrangement of the conveyance apparatus 600 will be described next with reference to FIGS. 3A and 3B. FIG. 3A is a view when the conveyance apparatus 600 is seen from the back (−Y direction). FIG. 3B is a view when the conveyance apparatus 600 is seen from a side (−X direction).

The conveyance apparatus 600 according to this embodiment includes a plurality of hands that respectively hold members and a support member that supports the plurality of hands and drives the plurality of hands in the height direction by driving the support member in the height direction (Z direction). More specifically, the conveyance apparatus 600 includes a first hand 601 that holds the mold 1, a second hand 602 that holds the substrate 2, a support member 612 that holds the first hand 601 and the second hand 602, and a driver 611 that drives the support member 612 in the height direction (Z direction). Although the conveyance apparatus 600 according to this embodiment can be controlled by the controller 700 of the planarization apparatus 100, a controller for controlling the conveyance apparatus 600 may be individually provided.

The first hand 601 is a holding member (end effector) that holds the mold 1 as the first member and is supported by the support member 612 through a first arm 604. The first hand 601 includes a holder 607 that sucks and holds the mold 1 by a vacuum suction scheme or the like. The holder 607 may be formed as a suction hole formed in the first hand 601 and communicating with a negative pressure generator (not shown). The first arm 604 is a mechanism for driving the first hand 601 in the X and Y directions. The first hand 601 is attached to one end portion of the first arm 604, and the support member 612 is attached to the other end portion. The first arm 604 may be provided with one or more joints between the one end portion and the other end portion. In addition, the first arm 604 may be provided with a fine motion mechanism 609 that drives the first hand 601 in the height direction so as to finely adjust the position of the first hand 601 in the height direction (Z direction).

The second hand 602 is a holding member (end effector) that holds the substrate 2 as a second member and is supported by the support member 612 through a second arm 605. The second hand 602 has a holder 608 that sucks and holds the substrate 2 by a vacuum suction scheme. The holder 608 may be formed as a suction hole formed in the second hand 603 and communicating with a negative pressure generator (not shown). The second arm 605 is a mechanism for driving the second hand 602 in the X and Y directions. The second hand 602 is attached to one end portion of the second arm 605, and the support member 612 is attached to the other end portion. The second arm 605 may be provided with one or more joints between the one end portion and the other end portion. In addition, the second arm 605 may be provided with a fine motion mechanism 610 that drives the second hand 602 in the height direction so as to finely adjust the position of the second hand 602 in the height direction.

The support member 612 supports the first hand 601 through the first arm 604 and supports the second hand 602 through the second arm 605. That is, the support member 612 is a member that supports the first hand 601 and the second hand 602. The support member 612 may be understood as a movable member that is driven by the driver 611.

The driver 611 is placed under the support member 612 and drives the support member 612 in the height direction (Z direction). The driver 611 can drive the first hand 601 and the second hand 602 in the height direction by driving the support member 612 in the height direction. That is, the driver 611 is a mechanism that is commonly used to drive the first hand 601 and the second hand 602 in the height direction.

In the conveyance apparatus 600, the actual heights of the first hand 601 and the second hand 602 driven by the driver 611 through the support member 612 sometimes shift from the design heights (target heights) due to changes over time and ambient environments. That is, a driving error sometimes occurs in the driver 611 that drives the first hand 601 and the second hand 602 through the support member 612. When such a driving error has occurred in the driver 611, the hand 601, the hand 602, the mold 1, or the substrate 2 may accidentally come into contact with other components in the planarization apparatus 100 and damage them during the conveyance of a member such as the mold 1 or the substrate 2. For this reason, the conveyance apparatus 600 is required to obtain a driving error in the driver 611 (that is, a driving error in the support member 612 driven by the driver 611) by a simple method and accurately control the conveyance of members by the hands 601 and 602.

Accordingly, the conveyance apparatus 600 according to this embodiment determines a driving error in the driver 611 in a mold conveyance process (first process) of causing the first hand 601 to convey the mold 1 (first member) to the mold chucks 212 (first holder). A substrate conveyance process (second process) of causing the second hand 602 to convey the substrate 2 (second member) to the substrate chuck 201 (second holder) is controlled based on a driving error in the driver 611 which is determined in the mold conveyance process. A mold conveyance process and a substrate conveyance process in the conveyance apparatus 600 according to this embodiment will be described below.

### Mold Conveyance Process

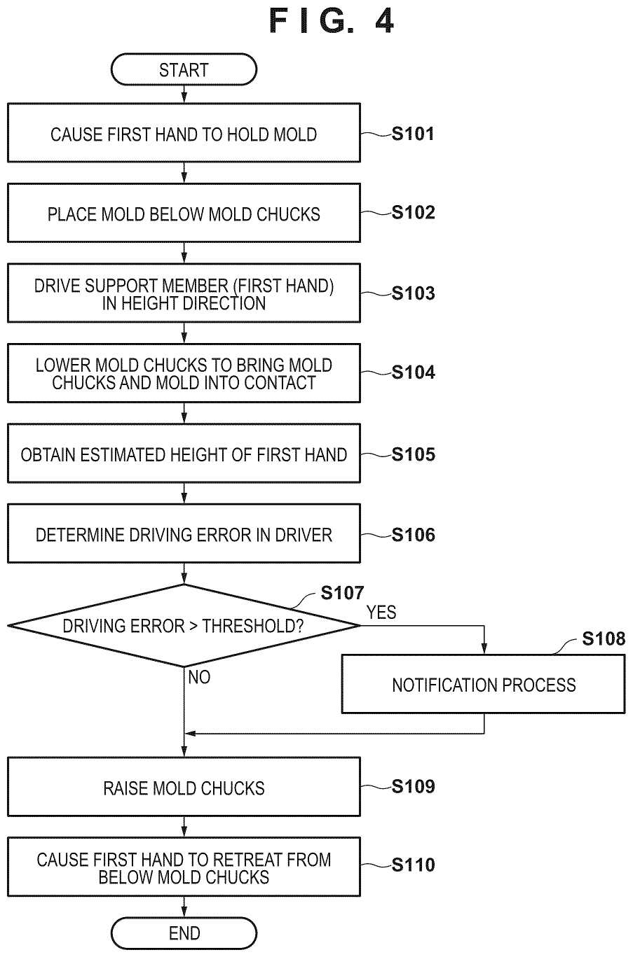

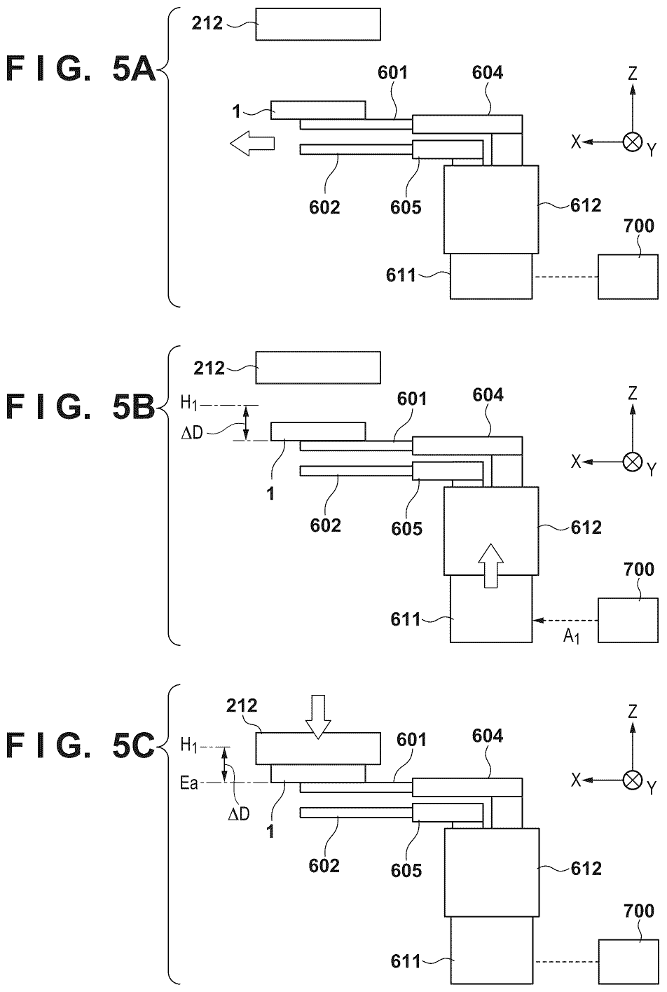

A mold conveyance process in the conveyance apparatus 600 according to this embodiment will be described first with reference to FIGS. 4, 5A, 5B, and 5C. FIG. 4 is a flowchart showing a mold conveyance process in the conveyance apparatus 600 according to this embodiment. The controller 700 of the planarization apparatus 100 can execute the flowchart of FIG. 4. When, however, a controller is individually provided for the conveyance apparatus 600, the controller may execute the flowchart. FIGS. 5A to 5C are schematic views for explaining the operations of the conveyance apparatus 600 and the planarization module 200 in a mold conveyance process. FIGS. 5A to 5C show only the constituent elements necessary for a description of the operations but do not show other constituent elements. Note that in the following description, “height direction” indicates the Z direction.

In step S101, the controller 700 causes the first hand 601 to hold the mold 1 loaded from the outside of the apparatus into the loading station 400. In step S102, as shown in FIG. 5A, the controller 700 places the mold 1 below the mold chucks 212 of the planarization module 200 by causing the first arm 604 to drive the first hand 601 in the X and Y directions.

In step S103, the controller 700 causes the driver 611 to drive the support member 612 (the first hand 601) so as to adjust the height of the first hand 601 to a target height H₁. For example, as shown in FIG. 5B, the controller 700 generates a drive command value A₁ for driving the driver 611 to adjust the height of the first hand 601 to the target height H₁ and supplies the drive command value A₁. Upon receiving the drive command value A₁ from the controller 700, the driver 611 drives the support member 612 (the first hand 601) in the height direction in accordance with the drive command value A₁. In this embodiment, however, the first hand 601 is not placed at the target height H₁ due to a driving error ΔD in the driver 611.

In step S104, the controller 700 causes the driving mechanisms 209 of the planarization module 200 to lower (move) the mold chucks 212 in the height direction so as to bring the mold 1 held by the first hand 601 into contact with the mold chucks 212 of the planarization module 200. For example, as shown in FIG. 5C, the controller 700 causes the driving mechanisms 209 to lower the mold chucks 212 while causing the mold detector 222 to detect the suction pressure of the mold chucks 212. This enables the controller 700 to determine, based on the detection result obtained by the mold detector 222, that the mold 1 on the first hand 601 has come into contact with the mold chucks 212. Upon determining that the mold 1 on the first hand 601 has come into contact with the mold chucks 212, the controller 700 causes the driving mechanisms 209 to stop lowering the mold chucks 212.

In step S105, the controller 700 estimates a height Ea (that is, a position in the height direction) of the first hand 601 based on the lowering (movement) of the mold chucks 212 in step S104. For example, as shown in FIG. 5C, the controller 700 can estimate the height Ea of the first hand 601 based on the thickness of the mold 1 and the height of the mold chucks 212 (holding surface). The thickness of the mold 1 is measured in advance by using an external measurement device or the like and stored in the controller 700. The height of the mold chucks 212 is detected by the position detector 221. In the following description, the height Ea of the first hand 601 which is estimated based on the lowering of the mold chucks 212 is sometimes called the “estimated height Ea”.

The controller 700 may obtain the height of the mold chucks 212 based on the lowering amount (movement amount) of the mold chucks 212 lowered by the driving mechanisms 209. For example, the controller 700 obtains, in advance, the position of the mold chucks 212 before the mold chucks 212 are lowered by the driving mechanisms 209 as a reference position (reference height). This enables the controller 700 to obtain the height of the mold chucks 212 at the time of contact between the mold 1 on the first hand 601 and the mold chucks 212 based on the reference position and the lowering amount of the mold chucks 212 which is detected by the position detector 221.

In step S106, the controller 700 determines the driving error ΔD in the driver 611 of the conveyance apparatus 600 based on the estimated height Ea obtained in step S105. For example, as shown in FIG. 5C, the controller 700 can determine the difference between the target height H₁ and the estimated height Ea of the first hand 601 as the driving error ΔD (for example, ΔD=H₁−Ea).

In step S107, the controller 700 determines whether the driving error ΔD in the driver 611, which is determined in step S106, is larger than a threshold. If the driving error ΔD is larger than the threshold, the process advances to step S108, in which the controller 700 performs a notification process. The notification process is a process of notifying the operator that the driving error ΔD in the driver 611 is larger than the threshold by using the notification unit 800. The controller 700 may interrupt the mold conveyance process additionally or alternatively with respect to the notification process or may stop executing the subsequent substrate conveyance process. If the driving error ΔD is equal to or less than the threshold, the process advances to step S109.

In step S109, the controller 700 causes the driving mechanisms 209 of the planarization module 200 to raise the mold chucks 212 in the height direction while the mold 1 is held by the mold chucks 212. In step S110, the controller 700 causes the first arm 604 to drive the first hand 601 in the X and Y directions to retreat the first hand 601 from below the mold chucks 212 of the planarization module 200. With the above process, the mold conveyance process is terminated.

### Substrate Conveyance Process

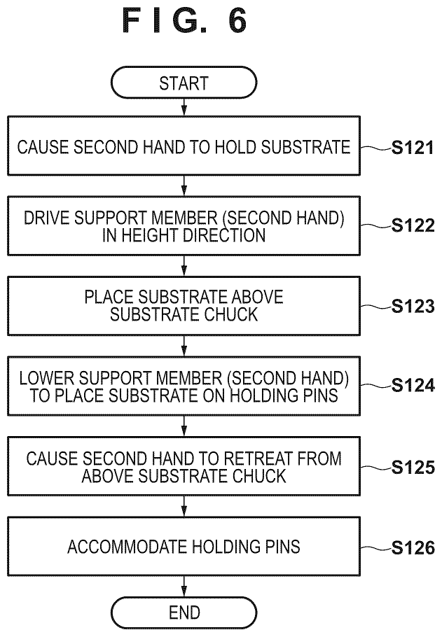

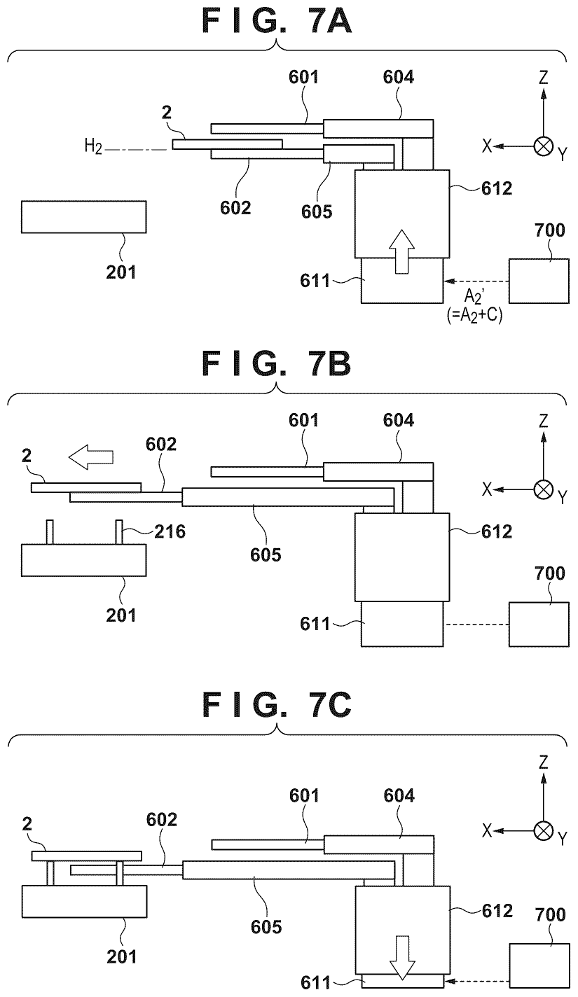

A substrate conveyance process in the conveyance apparatus 600 according to this embodiment will be described next with reference to FIGS. 6, 7A, 7B, and 7C. FIG. 6 is a flowchart showing the substrate conveyance process in the conveyance apparatus 600 according to the embodiment. The controller 700 of the planarization apparatus 100 can execute the flowchart of FIG. 6. When, however, a controller is individually provided for the conveyance apparatus 600, this flowchart may be executed by the controller. FIGS. 7A to 7C are schematic views for explaining the operations of the conveyance apparatus 600 and the planarization module 200 in the substrate conveyance process. FIGS. 7A to 7C show only the constituent elements necessary for a description of the operations but do not show other constituent elements.

In step S121, the controller 700 causes the second hand 602 to hold the substrate 2 loaded from the outside of the apparatus into the loading station 400 or the substrate 2 onto which the composition 3 is supplied by the supply module 300.

In step S122, the controller 700 causes the driver 611 to drive the support member 612 (the second hand 602) in the height direction so as to adjust the height of the second hand 602 to a target height H₂. At this time, the controller 700 controls the driving of the support member 612 (the second hand 602) by the driver 611 based on the driving error ΔD in the driver 611 which is determined in the above mold conveyance process. For example, as shown in FIG. 7A, the controller 700 determines a correction value C for correcting the driving error ΔD based on the driving error ΔD in the driver 611 which is determined in the mold conveyance process. The controller 700 then generates a drive command value A₂ for driving the driver 611 so as to adjust the height of the second hand 602 to the target height H₂, corrects the drive command value A₂ using the correction value C, and supplies a correction command value A₂′ obtained by the correction to the driver 611. Upon receiving the correction command value A₂′ from the controller 700, the driver 611 drives the support member 612 (the second hand 602) in the height direction in accordance with the correction command value A₂′. As described above, in this embodiment, the driver 611 in a substrate conveyance process controls the driving of the second hand 602 in the height direction based on the driving error ΔD in the driver 611 which is determined from the movement of the mold chucks 212 in the substrate conveyance process. This makes it possible to accurately place the second hand 602 at the target height H₂.

In step S123, as shown in FIG. 7B, the controller 700 places the substrate 2 above the substrate chuck 201 of the planarization module 200 by causing the second arm 605 to drive the second hand 602 in the X and Y directions. At this time, the controller 700 causes holding pins 216 to protrude from the holding surface (upper surface) of the substrate chuck 201.

In step S124, as shown in FIG. 7C, the controller 700 places the substrate 2 on the holding pins 216 protruding from the holding surface (upper surface) of the substrate chuck 201 by causing the driver 611 to lower the support member 612 (the second hand 602) in the height direction. In this case, in step S124, the controller 700 may control the lowering of the support member 612 (the second hand 602) by the driver 611 based on the driving error ΔD in the driver 611 which is determined from the movement of the mold chucks 212 in the mold conveyance process.

In step S125, the controller 700 retreats the second hand 602 from above the substrate chuck 201 of the planarization module 200 by causing the second arm 605 to drive the second hand 602 in the X and Y directions. Subsequently, in step S126, the controller 700 accommodates the holding pins 216 in the holding surface (upper surface) of the substrate chuck 201. With this operation, the substrate chuck 201 holds the substrate 2, and the substrate conveyance process is terminated.

As described above, the conveyance apparatus 600 according to this embodiment controls the driving of the second hand 602 in the height direction by the driver 611 in a substrate conveyance process based on the driving error ΔD in the driver 611 which is determined from the movement of the mold chucks 212 in a mold conveyance process. According to this embodiment, it is possible to obtain the driving error ΔD in the driver 611 by a simple method and accurately control the conveyance of a member by each of a plurality of hands (the first hand 601 and the second hand 602).

### Second Embodiment

The second embodiment of the present invention will be described. This embodiment will exemplify a case where the driving of a second hand 602 in the height direction by the driver 611 in a substrate conveyance process is controlled based on a driving error ΔD in the driver 611 which is determined by using a downward sensor 215 in a mold conveyance process. Note that this embodiment basically inherits the first embodiment, and matters other than those mentioned below can comply with the first embodiment. For example, the arrangement and the like of a planarization apparatus 100 are the same as those described in the first embodiment.

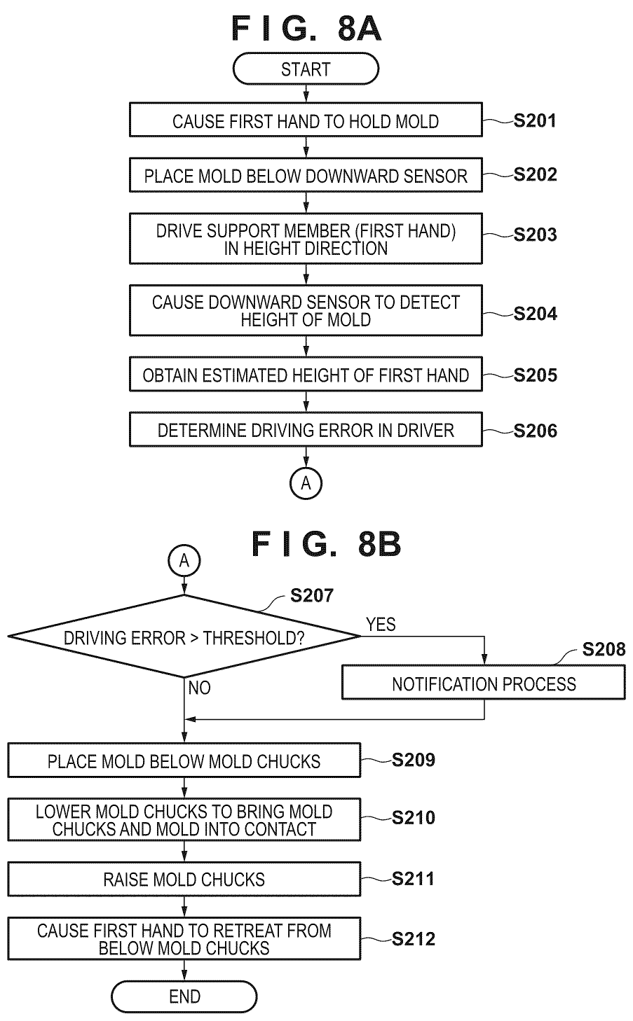

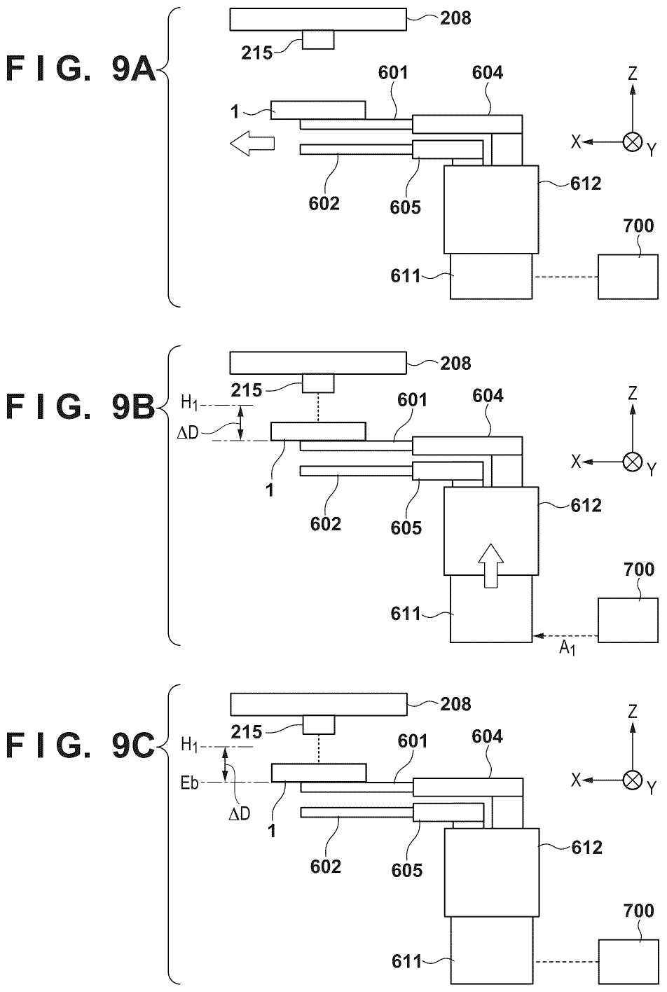

This embodiment differs from the first embodiment in a mold conveyance process. A mold conveyance process in a conveyance apparatus 600 according to the second embodiment will be described below with reference to FIGS. 8A, 8B, 9A, 9B, and 9C. FIGS. 8A and 8B are flowcharts showing a mold conveyance process in the conveyance apparatus 600 according to this embodiment. A controller 700 of the planarization apparatus 100 can execute the flowcharts of FIGS. 8A and 8B. When, however, a controller is individually provided for the conveyance apparatus 600, the controller may execute the flowcharts. FIGS. 9A to 9C are schematic views for explaining the operations of the conveyance apparatus 600 and a planarization module 200 in a mold conveyance process. FIGS. 9A to 9C show only the constituent elements necessary for a description of the operations but do not show other constituent elements.

In step S201, the controller 700 causes a first hand 601 to hold a mold 1 loaded from the outside of the apparatus into a loading station 400. Subsequently, in step S202, as shown in FIG. 9A, the controller 700 places the mold 1 below the downward sensor 215 of the planarization module 200 by causing a first arm 604 to drive the first hand 601 in the X and Y directions.

In step S203, as shown in FIG. 9B, the controller 700 causes the driver 611 to drive a support member 612 (the first hand 601) so as to adjust the height of the first hand 601 to a target height H₁. Since step S203 is a process similar to step S103 in the flowchart of FIG. 4, a detailed description of the step will be omitted. Subsequently, in step S204, the controller 700 causes the downward sensor 215 to detect the height of the mold 1 held by the first hand 601 below the downward sensor 215.

In step S205, the controller 700 estimates a height Eb (that is, a position in the height direction) of the first hand 601 based on the height of the mold 1 which is detected by the downward sensor 215 in step S204. For example, as shown in FIG. 9C, the controller 700 can estimate the height Eb of the first hand 601 based on the thickness of the mold 1 and the height of the mold 1 which is detected by the downward sensor 215. The thickness of the mold 1 is measured in advance by using an external measurement device or the like and stored in the controller 700. In the following description, the height Eb of the first hand 601 which is estimated based on the detection result obtained by the downward sensor 215 is sometimes called the “estimated height Ea”.

In step S206, the controller 700 determines the driving error ΔD in the driver 611 of the conveyance apparatus 600 based on the estimated height Eb obtained in step S205. For example, as shown in FIG. 9C, the controller 700 can determine the difference between a target height H₁ and the estimated height Eb of the first hand 601 as the driving error ΔD (for example, ΔD=H₁−Ea).

In step S207, the controller 700 determines whether the driving error ΔD in the driver 611 which is determined in step S206 is larger than a threshold. If the driving error ΔD is larger than the threshold, the process advances to step S208, in which the controller 700 performs a notification process. The notification process is a process of causing the notification unit 800 to notify the operator that the driving error ΔD in the driver 611 is larger than the threshold. The controller 700 may interrupt a mold conveyance process additionally or alternatively with respect to the notification process or may stop executing the subsequent substrate conveyance process. If the driving error ΔD is equal to or less than the threshold, the process advances to step S209.

In step S209, the controller 700 places the mold 1 below mold chucks 212 of the planarization module 200 by causing the first arm 604 to drive the first hand 601 in the X and Y directions. Note that when the downward sensor 215 is placed so as to detect the height of the mold 1 while the mold 1 is placed below the mold chucks 212, step S209 can be omitted.

In step S210, the controller 700 causes the driving mechanisms 209 of the planarization module 200 to lower (move) the mold chucks 212 in the height direction so as to bring the mold 1 held by the first hand 601 into contact with the mold chucks 212 of the planarization module 200. Since step S210 is a process similar to step S104 in the flowchart of FIG. 4, a detailed description of the step will be omitted.

In step S211, the controller 700 causes the driving mechanisms 209 of the planarization module 200 to raise the mold chucks 212 in the height direction while the mold 1 is held by the mold chucks 212. Subsequently, in step S212, the controller 700 retreats the first hand 601 from below the mold chucks 212 of the planarization module 200 by causing the first arm 604 to drive the first hand 601 in the X and Y directions. With the above process, the mold conveyance process is terminated.

As described above, the conveyance apparatus 600 according to this embodiment determines the driving error ΔD in the driver 611 by using the downward sensor 215. This embodiment can also obtain the driving error ΔD in the driver 611 by a simple method and accurately control the conveyance of members by a plurality of hands (the hands 601 and 602).

In this case, the mold conveyance process according to this embodiment uses the downward sensor 215 to estimate the height of the first hand 601, but upward sensors 214 may be used. In this case, the mold 1 is placed above the upward sensors 214 in step S202, and the height of the mold 1 can be detected by the upward sensors 214 in step S204. In addition, a substrate conveyance process in the embodiment can be performed in the same manner as in the substrate conveyance process described in the first embodiment.

### Third Embodiment

The third embodiment of the present invention will be described. In a conveyance apparatus 600, the interval between a first hand 601 and a second hand 602 in the height direction (Z direction) sometimes changes over time. This embodiment will exemplify the process of detecting a temporal change in the interval between the first hand 601 and the second hand 602 in the height direction (to be sometimes referred to as an interval detection process hereinafter). Note that this embodiment basically inherits the first embodiment, and matters other than those mentioned below can comply with the first embodiment. In addition, in the embodiment, the second embodiment may be additionally or alternatively applied to the first embodiment.

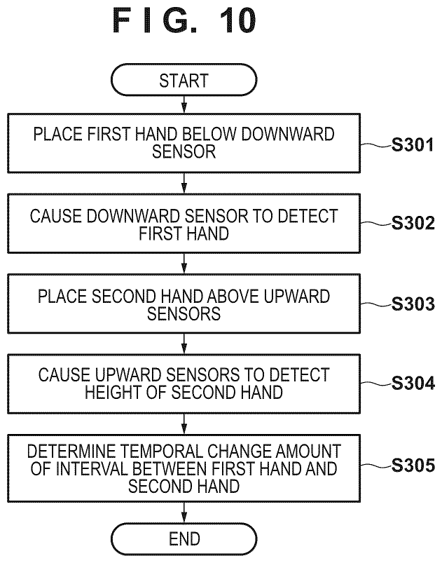

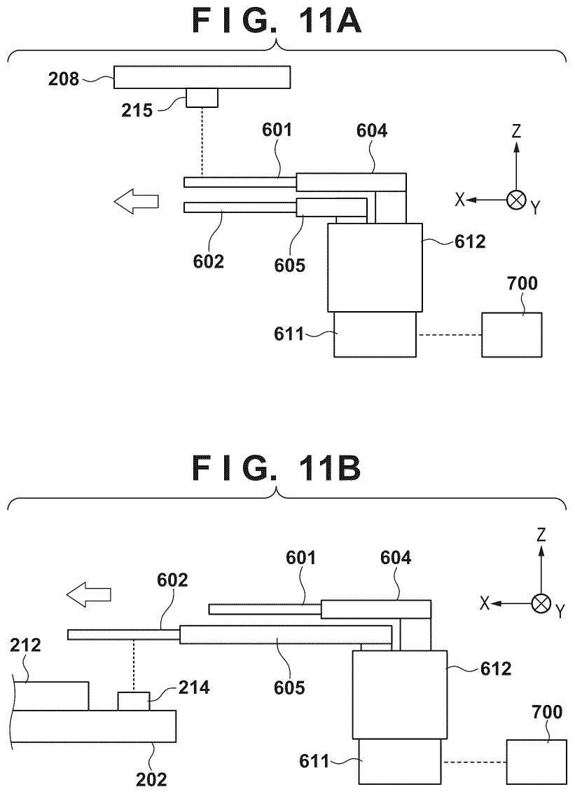

FIG. 10 is a flowchart showing an interval detection process. A controller 700 of a planarization apparatus 100 can execute the flowchart of FIG. 10. When, however, a controller is individually provided for the conveyance apparatus 600, the controller may execute the flowchart. In addition, FIGS. 11A and 11B are schematic views for explaining the operations of the conveyance apparatus 600 and a planarization module 200 in an interval correction process. FIGS. 11A and 11B show only the constituent elements necessary for a description of the operations but does not show other constituent elements.

In step S301, as shown in FIG. 11A, the controller 700 places the first hand 601 below a downward sensor 215 of the planarization module 200 by causing a first arm 604 to drive the first hand 601 in the X and Y directions. In step S302, the controller 700 causes the downward sensor 215 to detect the height of the first hand 601 placed below the downward sensor 215. This embodiment has exemplified the case where the height of the first hand 601 is detected by using the downward sensor 215, but the height of the first hand 601 may be detected by using upward sensors 214.

In step S303, as shown in FIG. 11B, the controller 700 places the second hand 602 above the upward sensors 214 of the planarization module 200 by causing the second arm 605 to drive the second hand 602 in the X and Y directions. In step S304, the controller 700 causes the upward sensors 214 to detect the height of the second hand 602 placed above the upward sensors 214. This embodiment has exemplified the case where the height of the second hand 602 is detected by using the upward sensors 214, but the height of the second hand 602 may be detected by using the downward sensor 215.

In step S305, the controller 700 determines a temporal change amount G of the interval between the first hand 601 and the second hand 602 in the height direction. For example, the controller 700 can obtain the difference between the height of the first hand 601, which is detected in step S302, and the height of the second hand 602, which is detected in step S304, and determine, as the temporal change amount G, the amount by which the difference has changed from a specified value (design value). In this case, the upward sensors 214 and the downward sensor 215 may be understood as detectors that detect a temporal change in the interval between the first hand 601 and the second hand 602 in the height direction.

The temporal change amount G determined in this manner is used when a driver 611 drives a support member 612 (the second hand 602) in a substrate conveyance process. That is, the controller 700 controls the driving of the support member 612 (the second hand 602) by the driver 611 in a substrate conveyance process based on a driving error ΔD in the driver 611 which is determined in a mold conveyance process and the temporal change amount G determined in the above manner. More specifically, the controller 700 corrects a drive command value for driving the driver 611 to adjust the height of the second hand 602 to a target height in the substrate conveyance process so as to reduce the driving error ΔD in the driver 611 and the temporal change amount G. This makes it possible to accurately control the conveyance of members by a plurality of hands (the first hand 601 and the second hand 602).

This embodiment has exemplified the case where the temporal change amount G is corrected by controlling the driving of the support member 612 (the second hand 602) by the driver 611. However, for example, the temporal change amount G may be corrected by a fine motion mechanism 609 of the first arm 604 or a fine motion mechanism 610 of a second arm 605.

### Fourth Embodiment

The fourth embodiment of the present invention will be described. In this embodiment, a modification of the conveyance apparatus 600 will be described. Note that the embodiment basically inherits the first embodiment, and matters other than those mentioned below can comply with the first embodiment. In addition, in the embodiment, the second embodiment may be additionally or alternatively applied to the first embodiment. In the fourth embodiment, the third embodiment may further be applied to the first embodiment.

FIG. 12A shows a conveyance apparatus 600a according to the first modification. As compared with the conveyance apparatus 600 shown in FIGS. 3A and 3B, the conveyance apparatus 600a shown in FIG. 12A includes a third hand 603 above a first hand 601. The third hand 603 holds an arbitrary plate member through a holder 606 (suction hole) using a vacuum suction scheme or the like. This plate member protects members held by the first hand 601 and/or a second hand 602 against ambient environments. The ambient environments include, for example, dust, gases, and heat. The third hand 603 is supported by the first arm 604 and can move together with the first hand 601. The third hand 603 is configured to retreat from above the first hand 601 when the mold 1 held by the first hand 601 is conveyed to mold chucks 212 of a planarization module 200.

FIG. 12B shows a conveyance apparatus 600b according to the second modification. As compared with the conveyance apparatus 600 shown in FIGS. 3A and 3B, the conveyance apparatus 600b shown in FIG. 12B includes a fourth hand 613 between the first hand 601 and the second hand 602. The fourth hand 613 holds an arbitrary plate member through a holder 614 (suction hole) using a vacuum suction scheme or the like. This plate member protects a member held by the second hand 602 against ambient environments. The fourth hand 613 is supported by the second arm 605 and can move together with the second hand 602.

### Embodiment of Article Manufacturing Method

An article manufacturing method according to the embodiment of the present invention is suitable for manufacturing an article, for example, a microdevice such as a semiconductor device or a device having a microstructure. The article manufacturing method according to this embodiment includes a shaping step of shaping, using the above-described shaping apparatus (imprint apparatus or planarization apparatus), a composition on a substrate, a processing step of processing the substrate having the composition molded in the molding step, and a manufacturing step of manufacturing an article from the substrate processed in the processing step. The manufacturing method further includes other known steps (oxidation, film formation, deposition, doping, planarization, etching, resist removal, dicing, bonding, packaging, and the like). The article manufacturing method of this embodiment is more advantageous than the conventional methods in at least one of the performance, quality, productivity, and production cost of the article.

The pattern of a cured product shaped using the shaping apparatus is used permanently for at least some of various kinds of articles or temporarily when manufacturing various kinds of articles. The articles are an electric circuit element, an optical element, a MEMS, a recording element, a sensor, a mold, and the like. Examples of the electric circuit element are volatile and nonvolatile semiconductor memories such as a DRAM, an SRAM, a flash memory, and an MRAM and semiconductor elements such as an LSI, a CCD, an image sensor, and an FPGA. Examples of the mold are molds for imprint and molds having flat surfaces (a plane template and a superstrate).

The pattern of the cured product is directly used as the constituent member of at least some of the above-described articles or used temporarily as a resist mask. After etching or ion implantation is performed in the substrate processing step, the resist mask is removed.

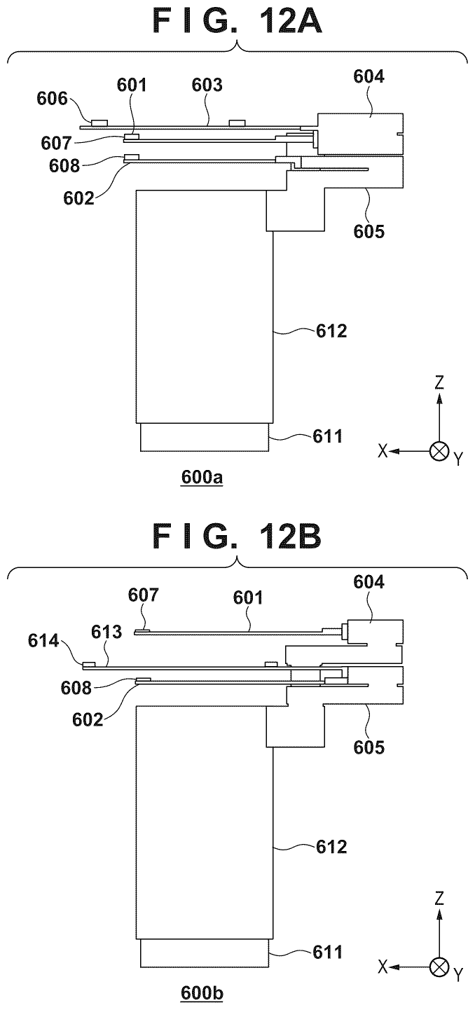

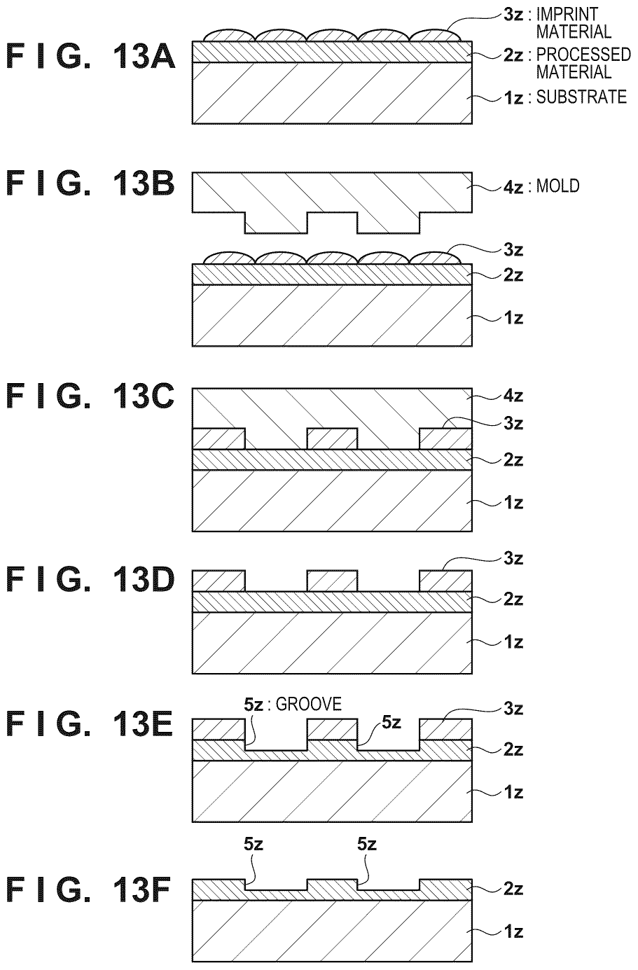

A practical article manufacturing method in a case where an imprint apparatus is used as a shaping apparatus will be described next. As shown FIG. 13A, a substrate 1z such as a silicon wafer with a processed material 2z such as an insulator formed on the surface is prepared. Next, an imprint material 3z is applied to the surface of the processed material 2z by an inkjet method or the like. A state in which the imprint material 3z is applied as a plurality of droplets onto the substrate is shown here.

As shown in FIG. 13B, a side of a mold 4z for imprint with a pattern having concave and convex portions is directed to face the imprint material 3z on the substrate. As shown FIG. 13C, the mold 4z and the substrate 1z to which the imprint material 3z has been applied are brought into contact with each other, and a pressure is applied. The gap between the mold 4z and the processed material 2z is filled with the imprint material 3z. In this state, when the imprint material 3z is irradiated with light as curing energy via the mold 4z, the imprint material 3z is cured.

As shown in FIG. 13D, after the imprint material 3z is cured, the mold 4z is separated from the substrate 1z, and the pattern of the cured product of the imprint material 3z is formed on the substrate 1z. In the pattern of the cured product, the concave portion of the mold corresponds to the convex portion of the cured product, and the convex portion of the mold corresponds to the concave portion of the cured product. That is, the pattern having concave and convex portions of the mold 4z is transferred to the imprint material 3z.

As shown in FIG. 13E, when etching is performed using the pattern of the cured product as an etching resistant mask, a portion of the surface of the processed material 2z where the cured product does not exist or remains thin is removed to form a groove 5z. As shown in FIG. 13F, when the pattern of the cured product is removed, an article with the grooves 5z formed in the surface of the processed material 2z can be obtained. Here, the pattern of the cured product is removed. However, instead of removing the pattern of the cured product after the process, it may be used as, for example, an interlayer dielectric film included in a semiconductor element or the like, that is, a constituent member of an article.

A specific article manufacturing method will be described in a case where a planarization apparatus is used as a shaping apparatus. As described above, the imprint apparatus uses, as a mold, a circuit pattern transfer mold on which an uneven pattern is formed. In contrast to this, the planarization apparatus uses a mold (a plane template or superstrate) having a flat surface on which no uneven pattern is formed. A mold such as a plane template or superstrate is used in a planarization apparatus that performs a planarization process of performing shaping such that a composition on a substrate is planarized by the flat surface. The planarization process includes a step of curing a curable composition by light irradiation or heating in a state in which the flat surface of the plane template is in contact with the curable composition supplied onto the substrate. As described above, this embodiment can be applied to a shaping apparatus configured to shape a composition on a substrate using a plane template.

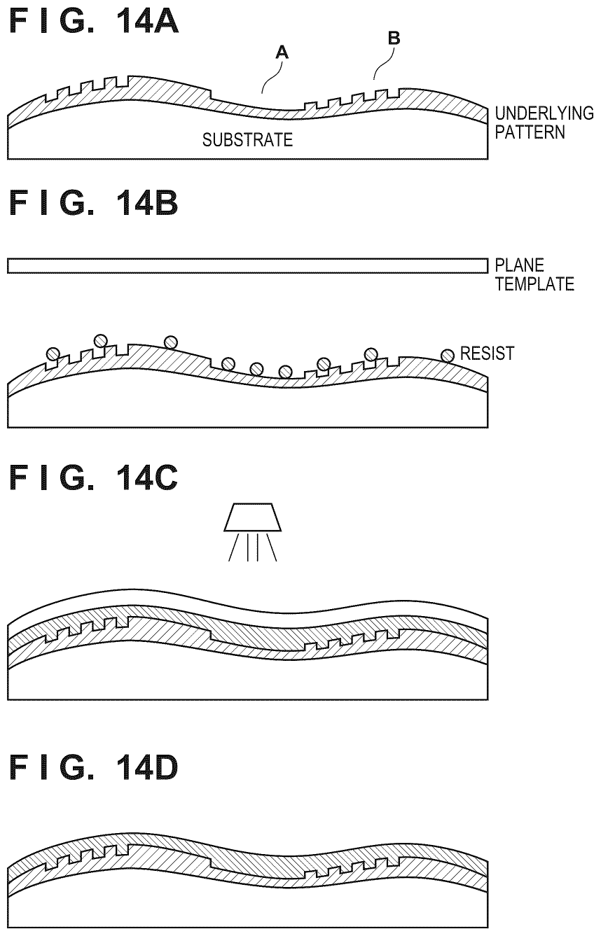

The underlying pattern on the substrate has an uneven profile derived from the pattern formed in the previous step. In particular, with the recent multilayered structure of a memory element, the substrate (process wafer) may have a step of about 100 nm. The step derived from a moderate undulation of the entire substrate can be corrected by the focus following function of an exposure apparatus (scanner) used in the photolithography step. However, an unevenness with a small pitch fitted in the exposure slit area of the exposure apparatus directly consumes the DOF (Depth Of Focus) of the exposure apparatus. As a conventional technique of planarizing the underlying pattern of a substrate, a technique of forming a planarization layer, such as SOC (Spin On Carbon) or CMP (Chemical Mechanical Polishing), is used. In the conventional technique, however, as shown in FIG. 14A, an unevenness suppressing rate of only 40% to 70% is obtained in the boundary portion between an isolated pattern region A and a repetitive dense (concentration of a line & space pattern) pattern region B, and sufficient planarization performance cannot be obtained. The unevenness difference of the underlying pattern caused by the multilayered structure tends to further increase in the future.

As a solution to this problem, U.S. Pat. No. 9,415,418 proposes a technique of forming a continuous film by application of a resist serving as a planarization layer by an inkjet dispenser and pressing by a plane template. Also, U.S. Pat. No. 8,394,282 proposes a technique of reflecting a topography measurement result on a substrate side on density information for each position to instruct application by an inkjet dispenser. An imprint apparatus IMP can particularly be applied as a planarization processing (planarization) apparatus for performing local planarization in a substrate surface by pressing a plane template as the mold against an uncured resist applied in advance.

FIG. 14A shows a substrate before planarization processing. In the isolated pattern region A, the area of a pattern convex portion is small. In the repetitive dense pattern region B, the ratio of the area of a pattern convex portion to the area of a pattern concave portion is 1:1. The average height of the isolated pattern region A and the repetitive dense pattern region B changes depending on the ratio of the pattern convex portion.

FIG. 14B shows a state in which the resist that forms the planarization layer is applied to the substrate. FIG. 14B shows a state in which the resist is applied by an inkjet dispenser based on the technique proposed in U.S. Pat. No. 9,415,418. However, a spin coater may be used to apply the resist. In other words, the imprint apparatus IMP can be applied if a step of pressing a plane template against an uncured resist applied in advance to planarize the resist is included.

As shown in FIG. 14C, the plane template is made of glass or quartz that passes ultraviolet light, and the resist is cured by irradiation of ultraviolet light from a light source. For the moderate unevenness of the entire substrate, the plane template conforms to the profile of the substrate surface. After the resist is cured, the plane template is separated from the resist, as shown in FIG. 14D.

### Other Embodiments

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-168866 filed on Sep. 28, 2023, which is hereby incorporated by reference herein in its entirety.

What is claimed is:

1. A conveyance apparatus comprising:
a first hand configured to hold a first member;
a second hand configured to hold a second member;
a support member configured to support the first hand and the second hand;
a driver configured to drive the first hand and the second hand in a height direction by driving the support member in the height direction; and
a controller configured to control a first process of conveying the first member to a first holder with the first hand and a second process of conveying the second member to a second holder with the second hand,
wherein the first holder is configured to move in the height direction,
wherein in the first process, after the first hand is driven in the height direction by the driver, the first holder is moved in the height direction so as to bring the first member held by the first hand into contact with the first holder, and
wherein the controller is configured to control driving of the second hand by the driver in the second process, based on a driving error in the driver which is determined from movement of the first holder in the first process.

2. The apparatus according to claim 1, wherein
in the first process, the first hand is driven to a target height by the driver, and
the controller is configured to obtain, as an estimated height, a height of the first hand based on movement of the first holder in the first process and determine a difference between the estimated height and the target height as the driving error.

3. The apparatus according to claim 2, wherein the controller is configured to obtain the estimated height based on a height of the first holder when the first member comes into contact with the first holder in the first process.

4. The apparatus according to claim 2, wherein the controller is configured to obtain the estimated height based on a movement amount by which the first holder is moved in the height direction so as to bring the first member into contact with the first holder in the first process.

5. The apparatus according to claim 1, wherein the controller is configured to correct, based on the driving error, a command value to be supplied to the driver to drive the second hand in the second process.

6. The apparatus according to claim 1, wherein the controller is configured to stop executing the second process if the driving error is larger than a threshold.

7. The apparatus according to claim 1, wherein the controller is configured to perform notification if the driving error is larger than a threshold.

8. The apparatus according to claim 1, further comprising a detector configured to detect a temporal change in an interval between the first hand and the second hand in the height direction,
wherein the controller is configured to control driving of the second hand by the driver in the second process further based on a detection result obtained by the detector.

9. A conveyance apparatus comprising:
a first hand configured to hold a first member;
a second hand configured to hold a second member;
a support member configured to support the first hand and the second hand;
a driver configured to drive the first hand and the second hand in a height direction by driving the support member in the height direction;
a controller configured to control a first process of conveying the first member to the first holder with the first hand and a second process of conveying the second member to a second holder with the second hand; and
a detector configured to detect a height of the first member held by the first hand,
wherein in the first process, after the first hand is driven in the height direction by the driver, the detector detects a height of the first member held by the first hand, and
the controller is configured to control driving of the second hand by the driver in the second process, based on a driving error in the driver which is determined from a detection result obtained by the detector in the first process.

10. A shaping apparatus for shaping a composition on a substrate by using a mold, the apparatus comprising:
a first holder configured to hold the mold;
a second holder configured to hold the substrate; and
a conveyance apparatus according to claim 1,
wherein the conveyance apparatus conveys the mold as the first member to the first holder and conveys the substrate as the second member to the second holder.

11. An article manufacturing method comprising:
shaping a composition on a substrate by using a shaping apparatus according to claim 10;
processing the substrate having the shaped composition; and
manufacturing an article from the processed substrate.
